(19) United States
(12) Patent Application Publication
(10) Pub. No.: US 2025/0328068 A1
(43) Pub. Date: Oct. 23, 2025

(54) REFLECTIVE MEMBER FOR EUV LITHOGRAPHY

(71) Applicant: ASML NETHERLANDS B.V., Veldhoven (NL)

(72) Inventors: Dong Seok NAM, San Jose, CA (US); Anthony YEN, Palo Alto, CA (US)

(73) Assignee: ASML NETHERLANDS B.V., Veldhoven (NL)

(21) Appl. No.: 18/868,388

(22) PCT Filed: Jun. 27, 2023
(86) PCT No.: PCT/EP2023/067468

§ 371 Date: Nov. 22, 2024

Related U.S. Application Data
(60) Provisional application No. 63/393,874, filed on Jul. 30, 2022.

(51) Int. Cl. G03F 1/24; G03F 7/00

(52) U.S. Cl. CPC G03F 1/24; G03F 7/70958

(57) ABSTRACT

A reflective member for use in an EUV lithographic apparatus, the reflective member including a multilayer stack which comprises a plurality of layers arranged in pairs, wherein: each pair comprises a first layer and a second layer; the first layer is formed of a material that comprises Si; and the second layer is formed of a material that comprises at least two selected from: Ru, Nb, and/or Mo, and wherein the second layer is configured to have, for radiation with a wavelength of approximately 13.5 nm, a refractive index that is less than or equal to 0.92 and an absorption coefficient that is less than or equal to 0.015.

### CROSS-REFERENCE TO RELATED APPLICATIONS

This application claims priority of U.S. application 63/393,874 which was filed on Jul. 30, 2022 and which is incorporated herein in its entirety by reference.

### FIELD

The present invention relates to a reflective member, a lithographic apparatus including a reflective member, a method of manufacturing a device including the use of a reflective member, an EUV mask, a lithographic apparatus including an EUV mask, and a method of manufacturing a device including the use of an EUV mask.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k1 is a process-dependent adjustment factor, also called the Rayleigh constant, and CD is the feature size (or critical dimension) of the printed feature. It follows from Equation (1) that reduction of the minimum printable size of features can be obtained in three ways: by shortening the exposure wavelength λ, by increasing the numerical aperture NA or by decreasing the value of k1.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring.

Collecting EUV radiation into a beam, directing it onto a mask and projecting the patterned beam onto a substrate is difficult, because it is not possible to make a refractive optical element for EUV radiation. Therefore, these functions have to be performed using reflectors (i.e. mirrors). Multilayer reflectors (also known as distributed Bragg reflectors) are commonly used, which comprise a number of layers arranged in pairs (also known as periods). Each pair comprises a relatively high refractive index layer and a relatively low refractive index layer. At each interface between layers, a proportion of radiation travelling through the multilayer reflector is reflected. The thickness of each pair is configured such that there is constructive interference between the radiation reflected at each interface. The reflectivity of multilayer reflectors used to reflect EUV radiation is typically around 70%. In a lithographic apparatus, there may be many multilayer reflectors used in series between the EUV source and the substrate. Consequently, the amount of radiation that reaches the substrate may be a small percentage of the EUV radiation generated.

Multilayer reflectors may be utilized in masks, which comprise, in addition to a multilayer stack, an absorber layer on a top surface of the multilayer stack. This absorber layer is patterned with an image that is to be projected onto the substrate. The absorber layer has a certain thickness, so when radiation is incident on the mask at an angle of incidence that is greater than zero, as is necessary with a reflective mask, 3D effects, such as shadowing of the incident radiation onto the mask occurs. This results in errors in the lithographic process, such as pattern placement errors and line width errors.

In multilayer reflectors, an effective reflectance plane can be defined as a plane below the surface of the multilayer reflector at a depth which represents the average depth of the reflections within the multilayer reflector. 3D effects (shadowing) become more significant when the effective reflectance plane is deeper below the surface of the multilayer reflector.

In current multilayer reflectors, the relatively high refractive index layer typically comprises Silicon (Si) and the relatively low refractive index layer typically comprises Molybdenum (Mo). An alternate configuration of multilayer reflector has been proposed in which the relatively high refractive index layer comprises Si and the relatively low refractive index layer comprises Ruthenium (Ru). Ru—Si multilayer reflectors exhibit a shallower effective reflectance plane than Mo—Si multilayer reflectors, so when they are used in masks, the 3D effects (shadowing) exhibited in are less than for Mo—Si multilayer reflectors. However, the reflectance of Ru—Si multilayer reflectors is lower than that of Mo—Si multilayer reflectors.

An object of the present invention is to provide a reflective member with superior properties (in terms of reflectance and 3D effects when used in an EUV mask) to reflective members that are currently available.

### SUMMARY OF THE INVENTION

In the present disclosure, there is provided a reflective member for use in an EUV lithographic apparatus, the reflective member comprising a multilayer stack which comprises a plurality of layers arranged in pairs, wherein: each pair comprises a first layer and a second layer; the first layer is formed of a material that comprises Si; and the second layer is formed of a material that comprises at least two of Ru, Nb, and Mo, and wherein the second layer is configured to have, for light with a wavelength of approximately 13.5 nm, a refractive index that is less than or equal to 0.92 and an absorption coefficient that is less than or equal to 0.015.

In the present disclosure, there is also provided a lithographic apparatus including a reflective member.

In the present disclosure, there is also provided a method of manufacturing a device including the use of a reflective member.

In the present disclosure, there is also provided an EUV photomask, comprising: a substrate; a multilayer stack, comprising a plurality of layers arranged in pairs; and a capping layer formed of a material that comprises at least two of Ru, Nb, and Mo, and wherein the capping layer is configured to have, for light with a wavelength of approximately 13.5 nm, a refractive index that is less than 0.92 and an absorption coefficient that is less than 0.015.

In the present disclosure, there is also provided a lithographic apparatus including an EUV photomask.

In the present disclosure, there is also provided a method of manufacturing a device including use of an EUV photomask.

### BRIEF DESCRIPTION OF THE DRAWINGS

Embodiments of the invention will now be described, by way of example only, with reference to the accompanying schematic drawings, in which corresponding reference symbols indicate corresponding parts.

FIG. 1 schematically depicts a lithographic apparatus.

FIG. 2 depicts a more detailed view of the lithographic apparatus.

FIG. 3 depicts, in cross-section, an example of an EUV mask.

FIG. 4 depicts, in cross-section, an EUV mask showing two reflected beams.

FIG. 5 depicts a plot of reflectance on the vertical axis and number of multilayer pairs on the horizontal axis for an Mo—Si multilayer stack and an Ru—Si multilayer stack.

FIG. 6 depicts a plot of absorption coefficient on the vertical axis and refractive index on the horizontal axis for several elements and alloys.

FIG. 7 depicts a plot of reflectance on the vertical axis and number of multilayer pairs on the horizontal axis for several multilayer stack configurations

FIG. 8 depicts a plot of reflectance on the vertical axis and wavelength on the horizontal axis for several multilayer stack configurations.

FIG. 9 depicts a plot of reflectance on the vertical axis and incident angle on the horizontal axis for a number of multilayer stack configurations.

### DETAILED DESCRIPTION

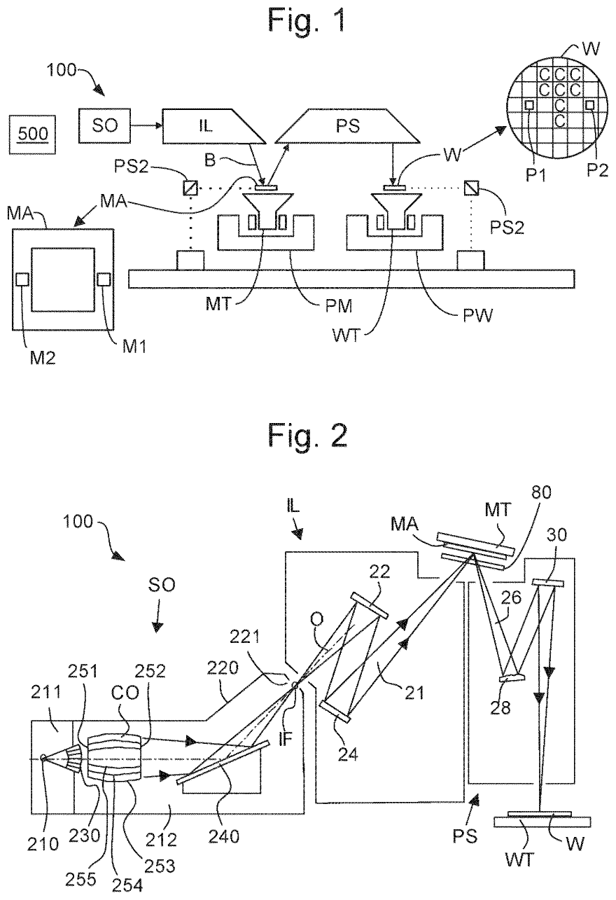

FIG. 1 schematically depicts a lithographic apparatus 100 including a source collector module SO according to one embodiment of the invention. The apparatus 100 comprises:

an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

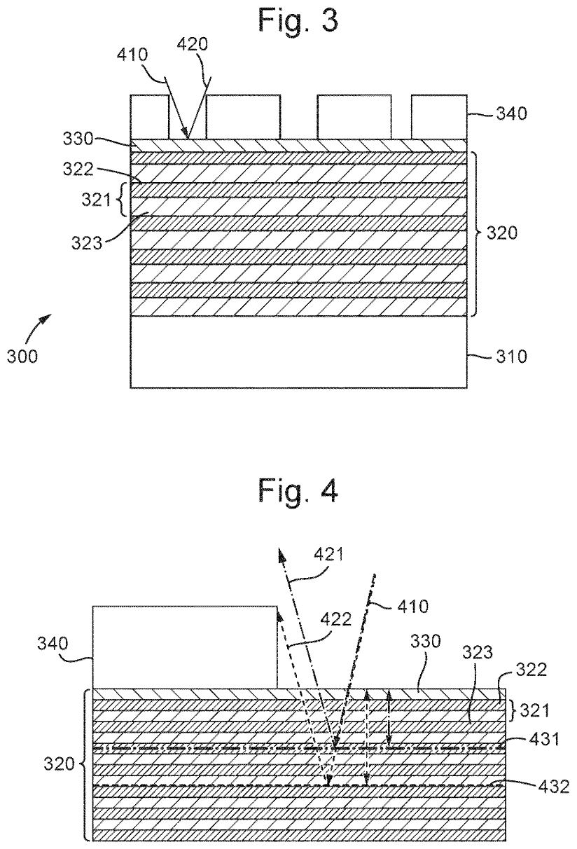

FIG. 3 depicts a mask 300 that could be used within an EUV lithographic apparatus to impart a required pattern to a radiation beam. The mask 300 is one example of a reflective member of the present invention.

The mask 300 shown in FIG. 3 includes a substrate 310, a multilayer stack 320, a capping layer 330, and an absorber layer 340. The substrate 310 is a component that provides a starting point for the manufacture of the multilayer stack 320. The reflective member disclosed herein may be employed with any composition of the substrate 310 known to be suitable to a person skilled in the art. For example, substrate 310 maybe formed of silicon oxide and titanium oxide (SiO2-TiO2). In general, the substrate 310 is formed of a material to which the material(s) of the multilayer stack 320 adheres to. A surface of the substrate 310 may be polished to form a smooth, flat surface to improve the adherence of the materials of the multilayer stack 320 to the substrate 310.

The multilayer stack 320 is formed of a plurality of layers 322, 323, which are arranged in pairs 321. Each pair comprises a relatively high refractive index layer 322 and a relatively low refractive index layer 323. That is, moving through the multilayer stack 320 in a direction perpendicular to an upper surface of the multilayer stack, the material changes from that of the relatively high refractive index layer 322 to that of a relatively low refractive 323. At each interface between layers (i.e. at the points in the multilayer stack at which EUV radiation moves from a relatively low refractive index layer 323 to a relatively high refractive index layer 322 or from a relatively high refractive index layer 322 to a relatively low refractive index layer 323), a proportion of the radiation is reflected. The thickness of each layer 322, 323 in the multilayer stack 320 is configured such that when light is reflected at each of the interfaces between different layers 322, 323 in the multilayer stack 320, the reflected beams are in-phase. This means that the reflections from each of the interfaces interfere with each other constructively to form the reflected beam.

In current multilayer stacks 320, the number of pairs in the multilayer stack 320 may be between 40 and 50. Each of the layers 322, 323 may be separated by an intermediary film (not shown) to prevent intermixing and silicide formation. The intermediary layers may, for example, be formed of Boron Carbide (B₄C). As stated above, the thickness of each layer is determined from the condition that the beams reflected at each interface constructively interfere, which is dependent on the wavelength of the radiation, as would be known to a person skilled in the art. As an example, relatively high refractive index layers 322 may have a thickness of between 3 and 5 nm, and relatively low refractive index layers 323 may have a thickness of between 2 and 4 nm.

The capping layer 330 may be located on the upper surface of the multilayer stack 320. The capping layer 330 is provided to improve the durability and chemical stability of the multilayer stack 320. The reflective member disclosed herein may be employed with any capping layer 330 known to be suitable to a person skilled in the art. As an example, the material of the capping layer may be the same as the material of the relatively high refractive index layers 322 or the material of the relatively low refractive index layers 323.

The absorber layer 340 may be located on an upper surface of the capping layer 330. The absorber layer 340 may be comprised of a single layer of material, or multiple layers of material. The absorber layer 340 is configured to absorb incident radiation. Therefore, in a mask configured for use in an EUV lithographic apparatus, the material of the absorber layer 340 is one that absorbs EUV radiation. The reflective member disclosed herein may be employed with an absorber layer 340 of any composition known to be suitable to a person skilled in the art. For example, the material of the absorber 340 may be formed of a material comprising tantalum nitride (TaN) or tantalum boron nitride (Ta—B—N), and the overall thickness of the absorber layer 340 may be between 50 nm and 70 nm. Alternatively, the absorber layer 340 may be formed of a material comprising Nickel (Ni), and the overall thickness of the absorber layer 340 may be between 25 nm and 35 nm.

The absorber layer 340 may be patterned in such a way that it contains an image that is to be projected onto a photo-sensitive film of a substrate. That is, the absorber layer 340 may cover some regions on the surface of the capping layer 330, but not others. In other words, some regions of the capping layer 330 may be exposed, and not others. In operation, EUV radiation is reflected by the mask 300 at the regions where the absorber layer 340 is not present, and absorbed in the regions where absorber layer 340 is present. The absorber layer 340 may initially be formed on the capping layer 330 such that it covers the entirety of the capping layer 330. The pattern may then be formed in the absorber layer 340 using a technique such as electron-beam lithography and any known etching process.

A mask configured for use in an EUV lithographic apparatus, such as the mask 300, could be formed layer by layer by a process such as physical vapor deposition (PVD), electron beam deposition (EBD), or chemical vapor deposition (CVD).

EUV radiation incident on a mask such as the mask 300 typically approaches the mask 300 from an angle of incidence (the angle between the incident beam and a line perpendicular to the surface at the point of incidence) that is greater than zero. This is so that the reflected beam travels along a different path than the incident beam. In a lithographic apparatus, the angle of incidence for a beam of EUV radiation incident on a mask 300 may be between 1° and 10° from the normal. For example, the angle of incidence may be 6°. As a consequence of the height of the absorber layer 340 above the capping layer 330 and the angle of incidence being greater than zero, undesirable shadowing of the exposed regions of the mask 300 occurs. This shadowing is where incident EUV radiation is blocked from reaching the exposed regions of the upper surface of the mask 300 by the absorber layer 340, or when reflected radiation is prevented from travelling outward from the mask 300 by the absorber layer 340. This shadowing can cause significant errors, such as pattern placement errors and line width errors. Errors arising from shadowing become more significant with increasing angle of incidence on the mask 300 and with increasing thickness of absorber layer 340. Errors resulting from shadowing also become more significant when an effective reflectance plane (a plane below the surface of the multilayer reflector which represents the average depth of the reflections within the multilayer reflector) becomes deeper. FIG. 4 illustrates two effective reflection planes 431, 432. The depth of the effective reflection plane in a multilayer stack 320 is dependent on the materials of the relatively high refractive index layers 322 and the relatively low refractive index layers 323. Specifically, the depth of the effective reflection plane is dependent on the refractive indices of the relatively high refractive index layers 322 and the relatively low refractive index layers 323. The effective reflection plane 432 is deeper than the effective reflection plane 431. When the incident EUV radiation beam 410 is reflected from the more shallow effective reflection plane 431, the reflected beam 421 is not impeded by the absorber layer 340 and is able to travel away from the mask 300. However, when the incident beam 410 is reflected at the deeper effective reflection plane 432, the reflected beam 422 is impeded by the absorber layer 340, and the reflected beam cannot travel away from the mask 300.

In a typical multilayer stack 320, the relatively high refractive index layer may be formed of a material that comprises Silicon (Si) and the relatively low refractive index layer may be formed of a material that comprises Molybdenum (Mo). More recently, it has been proposed that the relatively low refractive index layer can instead be formed of a material comprising Ruthenium (Ru). Ru—Si multilayer stacks may exhibit an effective reflectance plane which is less deep than the effective reflectance plane of an Mo—Si multilayer stack. For example, in FIG. 4, the effective reflectance plane 431 may be that of an Ru—Si multilayer stack 300, and the effective reflectance plane 432 may be that of an Mo—Si multilayer stack. For an Ru—Si multilayer stack 320, the effective reflectance plane 431 may be approximately 33 nm below the surface of the multilayer stack 320. For an Mo—Si multilayer stack 320, the effective reflectance plane 432 may be approximately 45 nm below the surface of the multilayer stack 320. The shallower effective reflectance plane 431 of the Ru—Si multilayer stack 320 means that errors caused by shadowing are less significant. However, the overall reflectance of an Ru—Si multilayer stack 320 may be approximately 5% less than the reflectance of an Mo—Si multilayer stack 320. Reflectance is defined as the fraction of energy that is reflected at an interface (Equation (2)). This reduction in reflectance corresponds to a throughput loss.

$$R = \frac{{E}_{r}}{{E}_{i}} \qquad ( 2 )$$

R=Reflectance; Eᵢ=Energy of the incident beam; Eᵣ=Energy of the reflected beam

Throughout the following description, values of refractive index (n) and absorption coefficient (k) are referred to. The method of measuring such values for a given material is not particularly limited. The values of refractive index (n) and absorption coefficient (k) may be determined from measured values of reflectivity and angle of incidence. Specifically, the values of refractive index (n) and absorption coefficient (k) may be determined by fitting a curve to a plot of the measured values of reflectivity and angle of incidence. The measurements of reflectivity and angle may be made utilizing a substrate coated with the material for which the values of refractive index (n) and absorption coefficient (k) are to be determined. The substrate may be a silicon wafer or mask plate. The thickness of the material coating may be between 30 nm and 50 nm.

Alternatively, values of refractive index (n) and absorption coefficient (k) may be determined from measurements made using an interferometer. As an example, the values of refractive index (n) and absorption coefficient (k) may be measured using an amplitude-division transmission interferometer. This may involve determining the phase-shift (q) and the visibility (V) of interferograms. A method of measuring the refractive index (n) and the absorption coefficient (k) is given in the following publication:
CHANG, Chang; ANDERSON, Erik; NAULLEAU, Patrick. Direct index of refraction measurement at extreme ultraviolet wavelength region with a novel interferometer. Optical Letters, 2001, 27(12).

Such a method may be used to measure the refractive index (n) and absorption coefficient (k) defined in the present invention. The apparatus used in the method may comprise: a radiation source; a small diameter hole to provide spatially coherent radiation; a diffraction grating which serves to effectively create orders of virtual sources out of the pinhole; a zoneplate which images the virtual sources formed at the diffraction grating to a plane at which a mask is situated; a mask comprising two openings which allow the zeroth and first order spots to pass; and a sensitive CCD camera. In the method, test materials are moved in and out of one of the openings in the mask, and the CCD camera records the resulting interferograms.

When the test material is present in one of the openings, the fringes of the interferograms shift in accordance with the refractive properties of the test material. The phase shift (φ) is the difference between two independently reconstructed phase maps of the interferograms. The refractive index (n) can then calculated using Equation (3), where λ is the wavelength and t is the thickness of the sample.

$$φ = \frac{2 π}{λ} tn \qquad ( 3 )$$

The relative optical intensity (α) after propagating through the sample is related to the observed visibility (V) of the interferograms by Equation (4).

$$V = \frac{2 \sqrt{α}}{1 + α} \qquad ( 4 )$$

From the relative optical intensity (a), absorption coefficient (k) can be calculated using the Equation (5).

$$α = {e}^{- \frac{4 π}{λ} kt} \qquad ( 5 )$$

Table 1 gives the refractive index (n) and absorption coefficient (k) for the elements Ru, Mo, Niobium (Nb) and a number of alloys containing those three elements for a wavelength of approximately 13.5 nm.

TABLE 1

| | n | k |
|---|---|---|
| Ru | 0.887 | 0.0171 |
| Mo | 0.9237 | 0.0064 |
| Nb | 0.9337 | 0.0052 |
| Ru₆Mo₂Nb₂ | 0.8936 | 0.0135 |
| Ru₄Mo₂Nb₄ | 0.8971 | 0.0116 |
| RuNb₂ | 0.8976 | 0.0109 |
| RuMo₂ | 0.900 | 0.0110 |
| RuMo | 0.897 | 0.0126 |

The reflectance of a multilayer stack 320 is dependent on the absorption coefficients of the materials from which the layers 322, 323 are formed. Ru has a higher absorption coefficient (k=0.0171) than Mo (k=0.0064), which explains why the reflectance of an Mo—Si multilayer stack 320 is greater than that of an Ru—Si multilayer stack 320. The depth of the effective reflectance plane (z_{eff}) is dependent on the difference in the refractive index (n) between the relatively high refractive index layers 322 and the relatively low refractive index layer 323. This is because a larger difference in the refractive index (n) between the relatively high refractive index layers 322 and the relatively low refractive index layer 323 results in a broader reflectivity band (a range of wavelength in which the reflectance is relatively high) for the multilayer stack 320. A broader reflectivity band results in a lower group delay (τ). The approximate depth of the effective reflectance plane (z_{eff}) is proportional to the group delay (τ), as shown in Equation (6). Therefore, a broader reflectivity band results in a shallower depth of the effective reflectance plane.

$${z}_{eff} ≅ \frac{1}{2} c τ \qquad ( 6 )$$

The lower the refractive index (n) of the relatively low refractive index layer 323, the greater the difference in refractive index (n) between the relatively high refractive index layer 323 and the relatively low refractive index layer 322. Ru has a lower refractive index (n=0.887) than Mo (n=0.9237), which explains why the effective reflectance plane 431 for an Ru—Si multilayer stack 320 is less deep than the effective reflectance plane 432 of an Mo—Si multilayer stack 320.

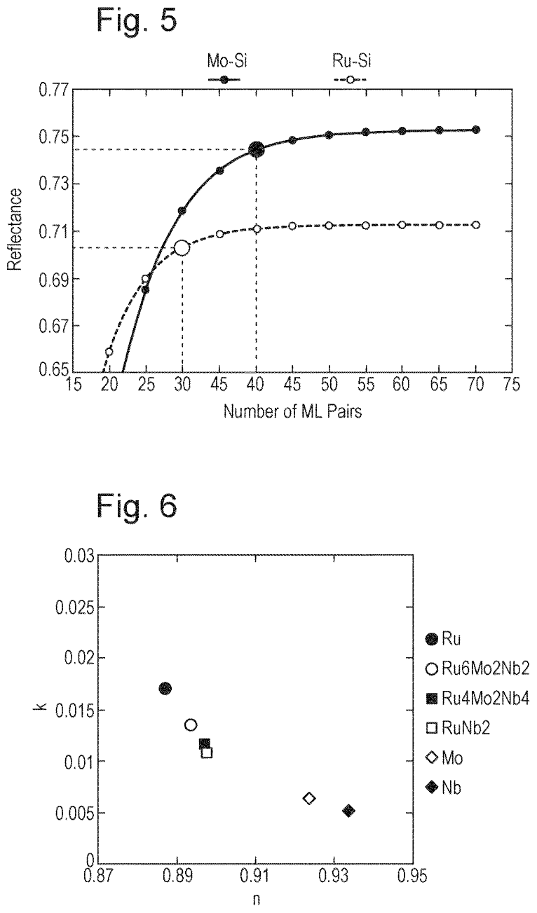

FIG. 5 shows how the reflectance of an Mo—Si multilayer stack 320 and an Ru—Si multilayer stack 320 varies with the number of pairs 321 in the multilayer stack 320. The plot is based on incident radiation with a wavelength of approximately 13.5 nm and angle of incidence of 6°. For both Mo—Si and Ru—Si multilayer stacks 320, whilst the number of pairs 321 in the multilayer stack 320 is relatively low, the reflectance increases rapidly with increasing number of pairs 431 in the multilayer stack 320. As the number of pairs 321 in the multilayer stack 320 increases, the rate of change of reflectance with respect to increasing number of pairs 321 decreases, and the reflectance tends towards a steady value. For an Ru—Si multilayer stack 320, the value of reflectance where the number of pairs is large (approximately 0.75) is lower than the value of reflectance for an Mo—Si multilayer stack 320 where the number of pairs is large (approximately 0.71). The Ru—Si multilayer stack 320 approximately reaches the steady reflectance value at a lower number of pairs (approximately 30) than the Mo—Si multilayer stack 320 (approximately 40).

The present disclosure relates to a material which, when used in the relatively low refractive index layer 323, can provide a multilayer stack 320 which combines the advantageous reflectance properties exhibited by an Mo—Si multilayer stack 320 and the advantageous effective reflectance plane properties exhibited by an Ru—Si multilayer stack 320. Specifically, the material is an alloy comprising at least two of Mo, Ru, and Niobium (Nb). As shown in Table 1, Nb has a refractive index (n=0.9337) that is higher than that of both Mo and Ru, and an absorption coefficient (n=0.9337) that is lower than that of both Mo and Ru. Consequently, an Nb—Si multilayer stack may have a superior reflectance than both Mo—Si and Ru—Si multilayer stacks 320, but a deeper effective reflection plane (z_{eff}). For light with a wavelength of approximately 13.5 nm, the alloy is composed such that the refractive index that is less than or equal to 0.92, and an absorption coefficient that is less than or equal to 0.015. For light with a wavelength of approximately 13.5 nanometres, the alloy may preferably exhibit a refractive index that is less than 0.91 and further preferably less than 0.9. For light with a wavelength of approximately 13.5 nm, the alloy may have preferably have an absorption coefficient (k) that is less than 0.014, preferably less than 0.013, and further preferably less than 0.012.

In addition to at least two of Ru, Nb, and Mo, the alloy may also comprise common impurities, such as Phosphorous, Sulphur, and Oxygen. The proportion of such impurities within the alloy may be such that they do not have a significant impact on the refractive index or absorption coefficient of the alloy. The percentage mass of impurities within the alloy may be less than 5%, preferably less than 1%, and further preferably less than 0.1%. That is, the alloy consists essentially of at least two of Ru, Nb, and Mo.

The alloy may comprise Nb. The alloy may contain Nb in an amount such that it cannot be considered a trace element. That is, the percentage mass of Nb in the alloy may be greater than 5%. The percentage mass of Nb in the alloy may preferably be greater than 20%, preferably greater than 40%, and further preferably greater than 60%. The percentage mass of Nb in the alloy may be less than 70%, preferably less than 50%, and further preferably less than 45%.

The alloy may comprise Ru. The alloy may contain Ru in an amount such that it cannot be considered a trace element. That is, the percentage mass of ruthenium in the alloy may be greater than 5%. Preferably, the percentage mass of ruthenium in the alloy may be greater than 30%, further preferably greater than 35%, and further preferably greater than 55%. The percentage mass of Ru in the alloy may be less than 85%, preferably less than 75%, and further preferably less than 70%.

The alloy may comprise Mo. The alloy may contain Mo in an amount such that it cannot be considered a trace element. The percentage mass of Mo in the alloy may be greater than or equal to 0%, preferably greater than 10%, and further preferably greater than 5%. The percentage mass of Mo in the material of the second layer may be less than 70%, preferably less than 50%, and further preferably less than 25%.

The properties of refractive index (n) and absorption coefficient (k) can be approximated by the weighted average of the refractive indices and absorption coefficients of the components of the alloy. Consequently, an expression can be formed approximately relating the composition of the alloy to the values of refractive index (n) and absorption coefficient (k). To facilitate this, a general formula for the alloy is given below:

$${Ru}_{x} {Nb}_{y} {Mo}_{z} \qquad ( 7 )$$

The subscript numbers in these alloys are intended to be representative of the molar ratios of each element in the alloy. The numbers do not suggest that the alloy is formed of a specific lattice structure in which the various components are held in a regular array such that the ratios are fixed integers. Because the alloy may contain impurities, the general formula of the alloy may be:

$${Ru}_{x} {Nb}_{y} {Mo}_{z} {I}_{a} \qquad ( 8 )$$

Wherein I represents the impurities in the alloy. I may represent a single impurity, or a plurality of impurities.

A weighted average expression for the refractive index (n) and absorption coefficient (k) of the alloy is as follows, where the values of n_{Ru} n_{Nb}, n_{Mo}, k_{Ru} k_{Nb}, and n_{Mo} are given in Table 1.

$${n}_{alloy} = {xn}_{Ru} + {yn}_{Nb} + {zn}_{Mo} \qquad ( 9 )$$

$${k}_{alloy} = {xk}_{Ru} + {yk}_{Nb} + {zk}_{Mo} \qquad ( 10 )$$

It should be noted that the weighted average method only provides an approximation. In fact, alloys may exhibit values of refractive index (n) and absorption coefficient (k) that are less (i.e. superior) to what would be expected from the weighted average calculation. For example, for an example alloy RuNb₂, the approximate refractive index (n) and absorption coefficient (k) from a weighted average of those values of the components are 0.903 and 0.131, respectively, but the actual refractive index (n) and absorption coefficient (k) are 0.898 and 0.0109, respectively.

The weighted average expression can be used to obtain an estimate for conditions of the alloy composition required to obtain a predetermined refractive index (nₘₐₓ) or a predetermined absorption coefficient (kₘₐₓ).

$${n}_{max} > {xn}_{Ru} + {yn}_{Nb} + {zn}_{Mo} \qquad ( 11 )$$

$${k}_{max} > {xk}_{Ru} + {yk}_{Nb} + {zk}_{Mo} \qquad ( 12 )$$

The predetermined refractive index (nₘₐₓ) may be 0.92, preferably 0.91, and further preferably less than 0.9. The predetermined absorption coefficient (kₘₐₓ) may be 0.015, preferably less than 0.014, further preferably less than 0.013, and further preferably less than 0.012. In one example alloy, the percentage mass of Ru may be greater than 50%, preferably greater than 55%, further preferably greater than 59%, less than 70%, preferably less than 65%, and further preferably less than 61%; the percentage mass of Mo may be greater than 10%, preferably greater than 15%, preferably greater than 19%, less than 30%, preferably less than 25%, and further preferably less than 21%; and the percentage mass of Nb may be less greater than 10%, preferably greater than 15%, further preferably greater than 19%, less than 30%, preferably less than 25%, and further preferably less than 21%. For instance, the alloy may be Ru₆Mo₂Nb₂.

In another example alloy, the percentage mass of Ru may be greater than 30%, preferably greater than 30%, further preferably greater than 39%, less than 50%, preferably less than 45%, and further preferably less than 41%; the percentage mass of Mo may be greater than 10%, preferably greater than 15%, further preferably greater than 19%, less than 30%, preferably less than 25%, and further preferably less than 21%; and the percentage mass of Nb may be greater than 30%, preferably greater than 35%, further preferably greater than 31%, less than 50%, preferably less than 45%, and further preferably less than 41%. For instance, the alloy may be Ru₄Mo₂Nb₄. These alloys are provided only as examples of alloys which may satisfy the requirements of the present invention.

The alloy may comprise Ru and Nb, but not Mo. That is, the alloy may consist of Ru, Nb, and the usual impurities. The percentage mass of Ru may be greater than 20%, preferably greater than 30%, further preferably greater than 32%, less than 40%, preferably less than 35%, and preferably less than 34%; and the percentage mass of Nb may be greater than 50%, preferably greater than 60%, further preferably greater than 66%, less than 80%, preferably less than 70%, and further preferably less than 67%. For instance the alloy may be RuNb₂.

The alloy may comprise Ru and Mo, but not Nb. That is, the alloy may consist of Ru, Nb, and the usual impurities. In an example, the percentage mass of Ru may greater than 20%, preferably greater than 30%, further preferably greater than 32%, less than 50%, preferably less than 40%, and further preferably less than 35%; and the percentage mass of Mo may be greater than 50%, preferably greater than 60%, further preferably greater than 65%, less than 80%, preferably less than 70%, and further preferably less than 68%. For instance, the alloy may be RuMo₂. In another example, the percentage mass of Ru may be greater than 30%, preferably greater than 40%, further preferably greater than 45%, less than 70%, preferably less than 60%, and further preferably less than 55%; and the percentage mass of Mo may be greater than 30%, preferably greater than 40%, further preferably greater than 45%, less than 70%, preferably less than 60%, and further preferably less than 55%. For instance, the alloy may be RuMo.

The values of refractive index (n) and absorption coefficient (k) are plotted on the graph depicted in FIG. 6, in which absorption coefficient (k) is on the vertical axis and refractive index (n) is on the horizontal axis, and the values are for a wavelength of approximately 13.5 nm. Also shown on the plot in FIG. 6 are the values of refractive index (n) and absorption coefficient (k) for the elements Mo, Ru, and Nb. For each of the three example alloys, the values of refractive index (n) and absorption coefficient (k) lie between those values of Mo and Ru. This means that if any of the example alloys were implemented as the relatively low refractive index layer 323 in a multilayer stack 320, the multilayer stack 320 would exhibit a superior reflectance to an Ru—Si multilayer stack 320 and a shallower effective reflectance plane than an Mo—Si multilayer stack. Further, the values of refractive index (n) and absorption coefficient vary depending on the composition of the alloy. Therefore, by tailoring the composition of an alloy comprising Mo, Ru, and Nb used in the relatively low refractive index layers 323 the multilayer stack 320, the properties of the multilayer stack 320 could be optimized for situational requirements.

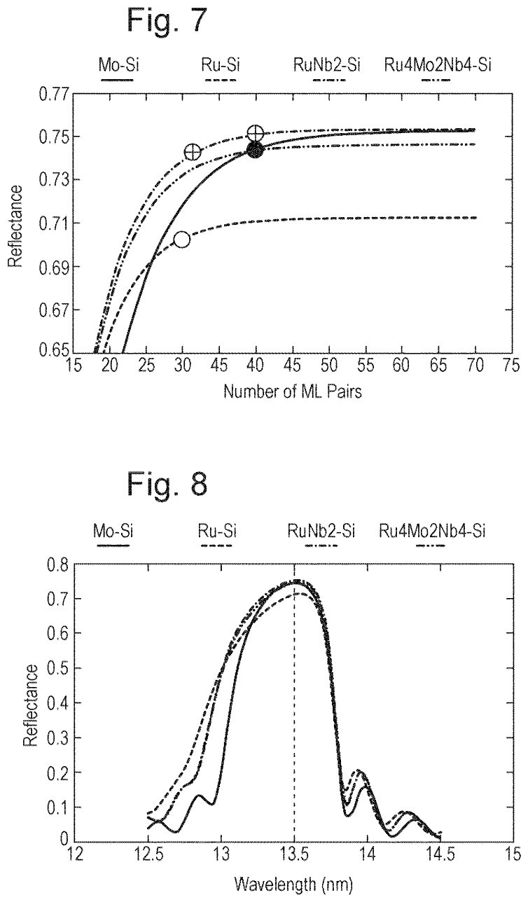

FIG. 7 depicts a plot with reflectance on the vertical axis and number of multilayer pairs on the horizontal axis. The plot is based on incident radiation with a wavelength of approximately 13.5 nm and an angle of incidence of 6°. As in FIG. 5, the values are plotted for an Mo—Si multilayer stack 320 and an Ru—Si multilayer stack 320, but FIG. 7 also includes the values for an RuNb₂—Si multilayer stack 320 and an Ru₄Mo₂Nb₄—Si 320 multilayer stack 320. The performance of the RuNb₂—Si multilayer stack 320 is superior to the other the other multilayer stacks 320. Specifically, as the number of pairs 321 increases, the RuNb₂—Si multilayer stack 320 tends to a higher reflectance than other multilayer stacks 320, including the Mo—Si multilayer stack 320. Further, whilst the number of pairs is relatively low (15-25), the rate of increase in the reflectance of the RuNb₂—Si multilayer stack with increasing number of pairs 321 is higher than that of the Mo—Si multilayer stack 320. This means that the RuNb₂—Si multilayer stack 320 approximately arrives at the steady state value of reflectance at a lower number of pairs 321 than the Mo—Si multilayer stack 320. As a result, the reflectance of the RuNb₂—Si multilayer stack with 40 pairs is higher than the reflectance of an Mo—Si multilayer stack with 40 pairs. To exhibit the same reflectance as a Mo—Si multilayer stack with 40 pairs, an RuNb₂ multilayer stack 320 requires less pairs (approximately 30-34).

FIG. 8 depicts a plot with reflectance on the vertical axis and wavelength in nm on the horizontal axis. The plot is based on multilayer stacks 320 with 40 pairs 431, and on radiation with an incident angle of 6°. The wavelength is the wavelength of the radiation incident of multilayer stack 320. The plot includes an Mo—Si multilayer stack 320, an Ru—Si multilayer stack 320, an RuNb₂—Si multilayer stack 320, and an Ru₄Mo₂Nb₄—Si multilayer stack 320. For all of the plots, the reflectance valve reaches a peak at an approximate wavelength of 13.5 nm. As would be expected from the previous graphs, the peak reflectance for the RuNb₂—Si multilayer stack 320 is highest, with the value being slightly larger than that of the Mo—Si multilayer stack 320. The peak reflectance for the Ru—Si multilayer stack 320 is the lowest. The Ru—Si multilayer stack 320 has the broadest reflectivity band and the Mo—Si multilayer stack 320 has the narrowest reflectivity band. The reflectivity band for an RuNb₂—Si multilayer stack 320 is broader than that of an Mo—Si multilayer stack 320, so the depth of the effective reflectance plane for an RuNb₂—Si multilayer stack 320 will be less than the depth of the effective reflectance plane for an Mo—Si multilayer stack 320.

Therefore, as well as exhibiting a higher reflectance, the RuNb₂—Si multilayer stack 320 will exhibit less significant shadowing (M3D) effects than an Mo—Si multilayer stack 320. Comparing the RuNb₂—Si multilayer stack 320 with the Ru—Si multilayer stack, it is clear that the RuNb₂—Si multilayer stack 320 exhibits a much higher reflectance, and it does this without resulting in a significant increase in the depth of the effective reflectance plane (compared to, for example, the increase in the depth of the effective reflectance plane if reflectance were to be increased by instead using an Mo—Si multilayer stack). Similar observations can be made for the Ru₄Mo₂Nb₄—Si multilayer stack 320. The observations would also apply to other alloys comprising at least two of Mo, Ru, and Nb, and having a refractive index less than or equal to 0.92 and an absorption coefficient that is less than or equal to 0.015.

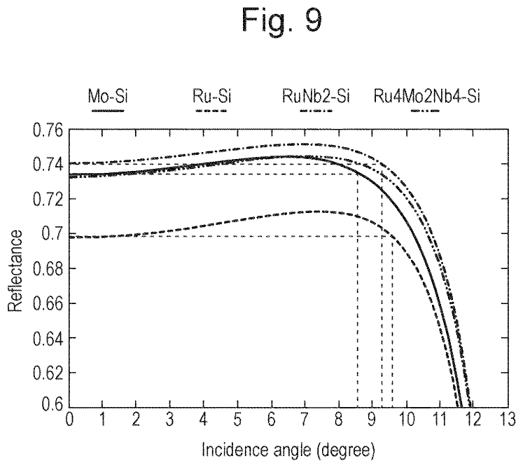

FIG. 9 depicts a plot with reflectance on the vertical axis and incident angle in degrees on the horizontal axis. The plot is based on a multilayer stack 320 with 40 pairs and radiation with a wavelength of approximately 13.5 nm. Shown in the plot are an Mo—Si multilayer stack 320, an Ru—Si multilayer stack 320, an RuNb₂—Si multilayer stack 320, and an Ru₄Mo₂Nb₄—Si multilayer stack 320. Generally, the change in reflectance as incidence angle increases is not significant below 9 degrees. In fact, the reflectance actually increases slightly from an incidence angle of 0 degrees to an incidence angle of around 7.5 degrees. When the incidence angle exceeds 9 degrees, the reflectance rapidly diminishes. As might be expected, the reflectance across the range of incident angle is much lower for an Ru—Si multilayer stack 320 than the Mo—Si multilayer stack 320. The performance of the RuNb₂—Si multilayer stack 320 is superior, exhibiting a higher reflectance over the full range of incidence angle.

Considering the above, a reflective member according to the present invention may preferably comprise less than or equal to 40 pairs 321 in the multilayer stack 320, further preferably less than 35 pairs 321, and further preferably less than 35 pairs 321. The number of pairs 321 in the multilayer stack 320 may preferably be greater than 20. Also, the effective reflectance plane of a reflective member according to the present invention may be less than 45 nm below uppermost surface of the multilayer stack 320, preferably less than 40 nm below the uppermost surface of the multilayer stack 320, and further preferably less than 35 nm below the surface of the multilayer stack. The reflectance of the reflective member (for radiation with a wavelength of 13.5 nm and an angle of incidence of) 6° may preferably be greater than 0.73, further preferably greater than 0.74, and further preferably greater than 0.75.

Whilst the above description has mainly referred to a mask 300, the invention is not limited to this implementation, and the multilayer stack 320 could be implemented in any reflective member. For example, the reflective member could be used in other components located within a lithographic apparatus, such as in an EUV scanner mirror.

When a capping layer 330 is present on an upper surface of the multilayer stack 320, the capping layer 320 may be formed of the same material as the relatively low refractive index layer 323 (that is, the alloy described in detail above). This may be advantageous even when the relatively low refractive layer 323 is not itself composed of the alloy. That is, the capping layer 330 may be formed of the alloy disclosed in this application when the relatively low refractive index layer 323 is formed of another material, such as molybdenum.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims and clauses set out below.

1. A reflective member for use in an EUV lithographic apparatus, the reflective member comprising a multilayer stack which comprises a plurality of layers arranged in pairs, wherein:
each pair comprises a first layer and a second layer;
the first layer is formed of a material that comprises Si; and
the second layer is formed of a material that comprises at least two of Ru, Nb, and Mo, and wherein the second layer is configured to have, for light with a wavelength of approximately 13.5 nm, a refractive index that is less than or equal to 0.92 and an absorption coefficient that is less than or equal to 0.015.

2. The reflective member according to clause 1, wherein the material of the second layer is configured to have, for light with a wavelength of approximately 13.5 nm, a refractive index that is less than 0.91 and preferably less than 0.9.

3. The reflective member according to clauses 1 or 2, wherein the material of the second layer is configured to have, for light with a wavelength of approximately 13.5 nm, an absorption coefficient that is less than 0.014, preferably less than 0.013, and further preferably less than 0.012.

4. The reflective member according to any of the preceding clauses, wherein the material of the second layer comprises Nb.

5. The reflective member according to any of the preceding clauses, wherein the material of the second layer comprises Ru.

6. The reflective member according to any of the preceding clauses, wherein the material of the second layer comprises Mo.

7. The reflective member according to any of the preceding clauses, wherein the material of the second layers consists of at least two of Ru, Nb, Mo, and the usual impurities.

8. The reflective member according to any of the preceding clauses, wherein the percentage mass of Nb in the material of the second layer is greater than 5%, preferably greater than 20%, preferably greater than 40%, and further preferably greater than 60%.

9. The reflective member according to any of the preceding clauses, wherein the percentage mass of Ru in the material of the second layer is greater than 30%, preferably greater than 35%, and further preferably greater than 55%.

10. The reflective member according to any of the preceding clauses, wherein the percentage mass of Mo in the material of the second layer is greater than or equal to 0%, preferably greater than 10%, and further preferably greater than 5%.

11. The reflective member according to any of the preceding clauses, wherein the percentage mass of Nb in the material of the second layer is less than 70%, preferably less than 50%, and further preferably less than 45%.

12. The reflective member according to any of the preceding clauses, wherein the percentage mass of Ru in the material of the second layer is less than 85%, preferably less than 75%, and further preferably less than 70%.

13. The reflective member according to any of the preceding clauses, wherein the percentage mass of Mo in the material of the second layer is less than 70%, preferably less than 50%, and further preferably less than 25%.

14. The reflective member according to any of the preceding clauses, wherein the material of the second layer is of the form RuₓNb_{y}Mo_{z}Impₐ, and wherein:
Imp represents at least one impurity
x+y+z+a=1; and
the composition of the material is such that 0.887x+0.9337y+0.9237z is less than 0.92, preferably less than 0.91, and further preferably less than 0.9.

15. The reflective member according to any of the preceding clauses, wherein the material of the second layer is of the form RuₓNb_{y}Mo_{z}Impₐ, and wherein:
Imp represents at least one impurity;
x+y+z+a=1; and
the composition of the material is such that 0.0171x+0.0052y+0.0064z is less than 0.015, preferably less than 0.014, further preferably less than 0.013, and further preferably less than 0.012.

16. The reflective member according to any of clauses 1 to 7, wherein the percentage mass of Ru is greater than 20%, preferably greater than 30%, further preferably greater than 32%, less than 40%, preferably less than 35%, and preferably less than 34%, and the percentage mass of Nb is greater than 50%, preferably greater than 60%, and further preferably greater than 66%, less than 80%, preferably less than 70%, and further preferably less than 67%.

17. The reflective member according to any of clauses 1 to 7, wherein: the percentage mass of Ru is greater than 50%, preferably greater than 55%, further preferably greater than 59%, less than 70%, preferably less than 65%, and further preferably less than 61%; the percentage mass of Mo is greater than 10%, preferably greater than 15%, further preferably greater than 19%, less than 30%, preferably less than 25%, and further preferably less than 21%; and the percentage mass of Nb is greater than 10%, preferably greater than 15%, further preferably greater than 19%, less than 30%, preferably less than 25%, and further preferably less than 21%.

18. The reflective member according to any of clauses 1 to 7, wherein: the percentage mass of Ru is greater than 30%, preferably greater than 35%, further preferably greater than 39%, less than 50%, preferably less than 45%, and further preferably less than 41%; the percentage mass of Mo is greater than 10%, preferably greater than 15%, further preferably greater than 19%, less than 30%, preferably less than 25%, and further preferably less than 21%; and the percentage mass of Nb is greater than 30%, preferably greater than 35%, further preferably greater than 39%, less than 50%, preferably less than 45%, and further preferably less than 41%.

19. The reflective member according to any of the preceding clauses, wherein the reflective member has an effective reflectance plane that is less than 45 nm below an uppermost surface of the multilayer stack, preferably less than 40 nm below the uppermost surface of the multilayer stack, and further preferably less than 35 nm below the uppermost surface of the multilayer stack.

20. The reflective member according to any of the preceding clauses, wherein the reflective member is configured for use as an EUV scanner mirror.

21. The reflective member according to any of clauses 1 to 19, wherein the reflective member is configured for use as an EUV photomask, and the reflective member further comprises a substrate on which the multilayer stack is formed and a capping layer positioned on the uppermost surface of the multilayer stack.

22. The reflective member according to clause 21, wherein the capping layer is formed of the same material as each second layer.

23. The reflective member according to clauses 21 or 22, wherein the reflective member further comprises an absorber layer positioned on an uppermost surface of the capping layer.

24. A lithographic apparatus including the reflective member of any of the preceding clauses.

25. A method of manufacturing a device including the use of the reflective member according to any of clauses 1 to 23.

26. An EUV photomask, comprising:
a substrate;
a multilayer stack, comprising a plurality of layers arranged in pairs; and
a capping layer formed of a material that comprises at least two of Ru, Nb, and Mo, and wherein the capping layer is configured to have, for light with a wavelength of approximately 13.5 nm, a refractive index that is less than 0.92 and an absorption coefficient that is less than 0.0015.

27. The EUV photomask according to clause 26, wherein the material of the capping layer is configured to have, for light with a wavelength of approximately 13.5 nm, a refractive index that is less than 0.91, and preferably less than 0.9.

28. The EUV photomask according to clauses 26 or 27, wherein the material of the capping layer is configured to have, for light with a wavelength of approximately 13.5 nm an absorption coefficient that is less than 0.014, preferably less than 0.013, and further preferably less than 0.012.

29. The EUV photomask according to clauses 26 to 28, wherein the material of the capping layer comprises Nb.

30. The EUV photomask according to any of clauses 26 to 29, wherein the material of the capping layer comprises Ru.

31. The EUV photomask according to any of clauses 26 to 30, wherein the material of the capping layer comprises Mo.

32. The EUV photomask according to any of clauses 26 to 31, wherein the material of the capping layer consists of at least two of Ru, Nb, Mo, and the usual impurities.

33. The EUV photomask according to any of clauses 26 to 32, wherein the percentage mass of Nb in the material of the capping layer is greater than 5%, preferably greater than 20%, preferably greater than 40%, and further preferably greater than 60%.

34. The EUV photomask according to any of clauses 26 to 33, wherein the percentage mass of Ru in the material of the capping layer is greater than 30%, preferably greater than 35%, and further preferably greater than 55%.

35. The EUV photomask according to any of clauses 26 to 34, wherein the percentage mass of Mo in the material of the capping layer is greater than or equal to 0%, preferably greater than 5%, and further preferably greater than 10%.

36. The EUV photomask according to any of clauses 26 to 35, wherein the percentage mass of Nb in the material of the capping layer is less than 70%, preferably less than 50%, and further preferably less than 45%.

37. The EUV photomask according to any of clauses 26 to 36, wherein the percentage mass of Ru in the material of the capping layer is less than 85%, preferably less than 75%, and further preferably less than 70%.

38. The EUV photomask according to any of clauses 26 to 37, wherein the percentage mass of Mo in the material of the capping layer is less than 70%, preferably less than 50%, and further preferably less than 25%.

39. The EUV photomask according to any of clauses 26 to 38, wherein the material of the second layer is of the form RuₓNb_{y}Mo_{z}Iₐ, where I represents at least one impurity, and the composition of the material is such that 0.887x+0.9337y+0.9237z is less than 0.92, preferably less than 0.91, and further preferably less than 0.9.

40. The EUV photomask according to any of clauses 26 to 39, wherein the material of the caping layer is of the form RuₓNb_{y}Mo_{z}Iₐ, where I represents at least one impurity, and the composition of the material is such that 0.0171x+0.0052y+0.0064z is less than 0.015, preferably less than 0.014, further preferably less than 0.013, and further preferably less than 0.012.

41. The EUV photomask according to any of clauses 26 to 32, wherein the percentage mass of Ru is greater than 20%, preferably greater than 30%, further preferably greater than 32%, less than 40%, preferably less than 35%, and preferably less than 34%, and the percentage mass of Nb is greater than 50%, preferably greater than 60%, and further preferably greater than 66%, and less than 80%, preferably less than 70%, and further preferably less than 67%.

42. The EUV photomask according to any of clauses 26 to 32, wherein: the percentage mass of Ru is greater than 50%, preferably greater than 55%, further preferably greater than 59%, less than 70%, preferably less than 65%, and further preferably less than 61%; the percentage mass of Mo is greater than 10%, preferably greater than 15%, further preferably greater than 19%, less than 30%, preferably less than 25%, and further preferably less than 21%; and the percentage mass of Nb is greater than 10%, preferably greater than 15%, further preferably greater than 19%, less than 30%, preferably less than 25%, and further preferably less than 21%.

43. The EUV photomask according to any of clauses 26 to 32, wherein: the percentage mass of Ru is greater than 30%, preferably greater than 35%, further preferably greater than 39%, less than 50%, preferably less than 45%, and further preferably less than 41%; the percentage mass of Mo is greater than 10%, preferably greater than 15%, further preferably greater than 19%, less than 30%, preferably less than 25%, and further preferably less than 21%; and the percentage mass of Nb is greater than 30%, preferably greater than 35%, further preferably greater than 39%, less than 50%, preferably less than 45%, and further preferably less than 41%.

44. A lithographic apparatus including the EUV photomask according to any of clauses 26 to 43.

45. A method of manufacturing a device including use of the EUV photomask according to any of clauses 26 to 43.

1. A reflective member for use in an EUV lithographic apparatus, the reflective member comprising a multilayer stack which comprises a plurality of layers arranged in pairs, wherein:
each pair comprises a first layer and a second layer;
the first layer is formed of a material that comprises Si; and
the second layer is formed of a material that comprises at least two selected from: Ru, Nb, and/or Mo, and wherein the second layer is configured to have, for radiation with a wavelength of approximately 13.5 nm, a refractive index that is less than or equal to 0.92 and an absorption coefficient that is less than or equal to 0.015.

2. The reflective member according to claim 1, wherein the material of the second layer is configured to have, for radiation with a wavelength of approximately 13.5 nm, a refractive index that is less than 0.91.

3. The reflective member according to claim 1, wherein the material of the second layer is configured to have, for radiation with a wavelength of approximately 13.5 nm, an absorption coefficient that is less than 0.014.

4. The reflective member according to claim 1, wherein the material of the second layer comprises Nb.

5. The reflective member according to claim 1, wherein the material of the second layers consists of at least two selected from: Ru, Nb, and/or Mo, and the usual impurities.

6. The reflective member according to claim 1, wherein the material of the second layer comprises Nb and wherein the percentage mass of Nb in the material of the second layer is greater than 5%.

7. The reflective member according claim 1, wherein the material of the second layer comprises Ru and wherein the percentage mass of Ru in the material of the second layer is greater than 30.

8. The reflective member according to claim 1, wherein the material of the second layer comprises Mo and wherein the percentage mass of Mo in the material of the second layer is greater than 10%.

9. The reflective member according to claim 1, wherein the material of the second layer comprises Nb and wherein the percentage mass of Nb in the material of the second layer is less than 70%.

10. The reflective member according to claim 1, wherein the material of the second layer comprises Ru and wherein the percentage mass of Ru in the material of the second layer is less than 85%.

11. The reflective member according to claim 1, wherein the material of the second layer comprises Mo and wherein the percentage mass of Mo in the material of the second layer is less than 70%.

12. The reflective member according to claim 1, wherein the material of the second layer is of the form RuₓNb_{y}Mo_{z}Impₐ, and wherein:
Imp represents at least one impurity
x+y+z+a=1; and
the composition of the material is such that 0.887x+0.9337y+0.9237z is less than 0.92.

13. The reflective member according to claim 1, wherein the material of the second layer is of the form RuₓNb_{y}Mo_{z}Impₐ, and wherein:
Imp represents at least one impurity;
x+y+z+a=1; and
the composition of the material is such that 0.0171x+0.0052y+0.0064z is less than 0.015.

14. The reflective member according to claim 1, wherein the material of the second layer comprises Ru and Nb and wherein the percentage mass of Ru is greater than 20% and less than 40%, and the percentage mass of Nb is greater than 50% and less than 80%.

15. The reflective member according to claim 1, wherein the material of the second layer comprises Ru, Mo and Nb and:
the percentage mass of Ru is greater than 50% and less than 70%;
the percentage mass of Mo is greater than 10% and less than 30%; and
the percentage mass of Nb is greater than 10% and less than 30%.

16. The reflective member claim 1, wherein the material of the second layer comprises Ru, Mo and Nb and:
the percentage mass of Ru is greater than 30% and less than 50%;
the percentage mass of Mo is greater than 10% and less than 30%; and
the percentage mass of Nb is greater than 30% and less than 50%.

17. The reflective member according to claim 1, wherein the reflective member has an effective reflectance plane that is less than 45 nm below an uppermost surface of the multilayer stack.

18. The reflective member according to claim 1, wherein the reflective member is configured for use as an EUV scanner mirror.

19. The reflective member according to claim 1, wherein the reflective member is configured for use as an EUV photomask, and the reflective member further comprises a substrate on which the multilayer stack is formed and a capping layer positioned on the uppermost surface of the multilayer stack.

20. An EUV photomask, comprising:
a substrate;
a multilayer stack, comprising a plurality of layers arranged in pairs; and
a capping layer formed of a material that comprises at least two selected from: Ru, Nb, and/or Mo, and wherein the capping layer is configured to have, for radiation with a wavelength of approximately 13.5 nm, a refractive index that is less than 0.92 and an absorption coefficient that is less than 0.0015.
